(19) United States
(12) Patent Application Publication
(10) Pub. No.: US 2008/0023748 A1
(43) Pub. Date: Jan. 31, 2008

(54) Self-aligned contacts to source/drain regions

(75) Inventor: Yi Ding, San Jose, CA (US)

Correspondence Address: MACPHERSON KWOK CHEN & HEID LLP, 2033 GATEWAY PLACE, SUITE 400, SAN JOSE, CA, 95110, US

(73) Assignee: ProMOS Technologies Pte. Ltd.

(21) Appl. No.: 11/495,008

(22) Filed: Jul. 27, 2006

(51) Int. Cl. H01L 29/788

(52) U.S. Cl. 257/315

(57) ABSTRACT

In some embodiments, when etching a dielectric to form a self-aligned contact opening to a source/drain region (160) of a transistor, the gate structure (220) is protected on top with a non-conformal layer (M3), possibly silicon, deposited so that it is thicker over the gate than over the source/drain region. The silicon may be insulated from the gates by another dielectric layer (M2). When the non-conformal layer is etched over the source/drain region, it may also be etched on top of the gate structure, but the gate structure remains protected due to the greater thickness of the non-conformal layer.

### FIELD OF THE INVENTION

This invention relates to integrated circuits and, more particularly, to forming contacts to transistors' source/drain regions.

### BACKGROUND OF THE PRIOR ART

FIGS. 1A-1C are a simplified illustration of a prior art process forming a self-aligned contact to a source/drain region shared by two adjacent transistors. A silicon dioxide layer 110 (gate oxide) is formed on a silicon substrate 120. A polysilicon layer 130 (gate polysilicon) is formed on oxide 110. A protective dielectric 140 is formed on polysilicon 130. Dielectric 140 typically includes a silicon nitride layer to protect the gates during a subsequent etch of a self-aligned source/drain contact opening. Dielectric 140 and polysilicon 130 are patterned using a single photolithographic mask (not shown) to define the transistor gates. The structure is heated to oxidize the sidewalls of polysilicon 130 and thus form silicon oxide layer 144 on the sidewalls.

Dielectric spacers 150 (FIG. 1B) comprising silicon nitride are formed over the sidewalls of gates 130 and features 140. Spacers 150 include a layer deposited and etched anisotropically without a mask. One or more doping steps are performed to form source/drain regions 160 (i.e. 160.1, 160.2, 160.3). The structure is heated to anneal the source/drain regions. Thick interlevel dielectric (ILD) 170 is formed on the structure from silicon dioxide. A photoresist layer 180 (FIG. 1C) is formed on oxide 170 and photolithographically patterned to have an opening over the source/drain region 160.2 shared by the two transistors. The opening in the photoresist can overlap the transistor gates 130.

Oxide 170 is etched through the photoresist opening. As a result, an opening is formed in oxide 170 to expose the source/drain region 160.2 (oxide 110 may also have to be removed if it has not been removed over the source/drain region 160.2 in an earlier step, e.g. the step immediately after the patterning of polysilicon 130 at the stage of FIG. 1A). The oxide etch is selective to silicon nitride. The gates 130 are protected by the nitride in layers 140, 150 and hence are not exposed. The photoresist is removed, and a conductive layer (not shown) is deposited into the opening in oxide 170 to provide a contact to the source/drain region 160.2. See e.g. U.S. Pat. No. 6,573,602 issued Jun. 3, 2003 to Seo et al.

### SUMMARY

This section summarizes some features of the invention. Other features are described below. The invention is defined by the appended claims.

I have observed that the process of FIGS. 1A-1C is difficult to perform if the gates must be silicided by a self-aligned silicide (“salicide”) process (i.e. depositing a metal layer, heating the structure to react the metal with the silicon, then removing the unreacted metal). Some salicide films (e.g. cobalt silicide) are easily damaged by high temperatures such as may be needed for the gate oxidation (formation of oxide 144), the anneal of source/drain regions 160, etc.

In some embodiments of the present invention, when contact openings are etched to source/drain regions, the gates are protected on top by a non-conformal layer (possibly a silicon layer), deposited so that it is thicker over the gates than over the source/drain regions. (The non-conformal silicon layer may be insulated from the gates by another dielectric layer.) When the non-conformal layer is etched over the source/drain regions, it may also be etched on top of the gates, but the gates remain protected by the greater thickness of the non-conformal layer.

The invention may be used with or without silicided gates and with or without a nitride layer over the gates. In some embodiments, the transistors may be part of non-volatile memory cells. Each transistor includes a floating gate (conductive) and a control gate overlying the floating gate. The control gate may or may not be silicided. If the dimensions are small, a high aspect ratio may be provided for the non-conformal layer deposition, to ensure a high thickness differential (high non-conformity) for the non-conformal layer.

Self-aligned drain contacts in non-volatile memories are important, among other things, to provide a tight Vt (threshold voltage) distribution. The Vt distribution is affected by the parasitic capacitance between the floating gate and the drain contact (bitline contact). If the drain contact is shared by two adjacent cells, and is not self-aligned (i.e. is defined by a photolithographic mask), then a mask shift could make the contact closer to the floating gate of one of the cells and farther from the floating gate of the other one of the two cells. The Vt distribution may become less tight as a result. See for example, LEE, Jae-Duk, et al, “Effects of floating-gate interference on NAND flash memory cell operation”, IEEE Electron Device Letters, May 2002, Volume 23, Issue 5. pp: 264-266.

The invention is not limited to non-volatile memories and other features and advantages described above. The invention is defined by the appended claims.

### BRIEF DESCRIPTION OF THE DRAWING

The foregoing objects and features of the present invention may become more apparent by referring to the drawing in which:

FIGS. 1A-1C are vertical cross sections of integrated circuits to provide a simplified illustration of a prior art process for forming a self-aligned contact to a source/drain region shared by two adjacent transistors.

FIG. 2A shows a vertical cross-section of an integrated circuit during fabrication according to some embodiments of the present invention.

FIG. 2B is a plan view of the integrated circuit of FIG. 2A.

FIGS. 2C, 2D, 2E, 2F, 3, 4, 5 show vertical cross-sections of integrated circuits during fabrication according to some embodiments of the present invention.

### DESCRIPTION OF SOME EMBODIMENTS

This section describes some embodiments of the invention. The invention is not limited to these embodiments. In particular, the materials used, the dimensions, and other features are not limiting unless required by the appended claims.

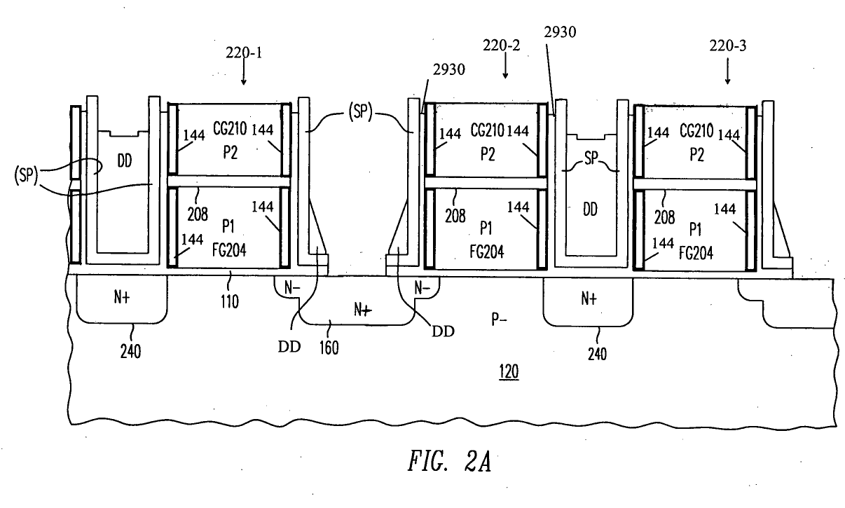

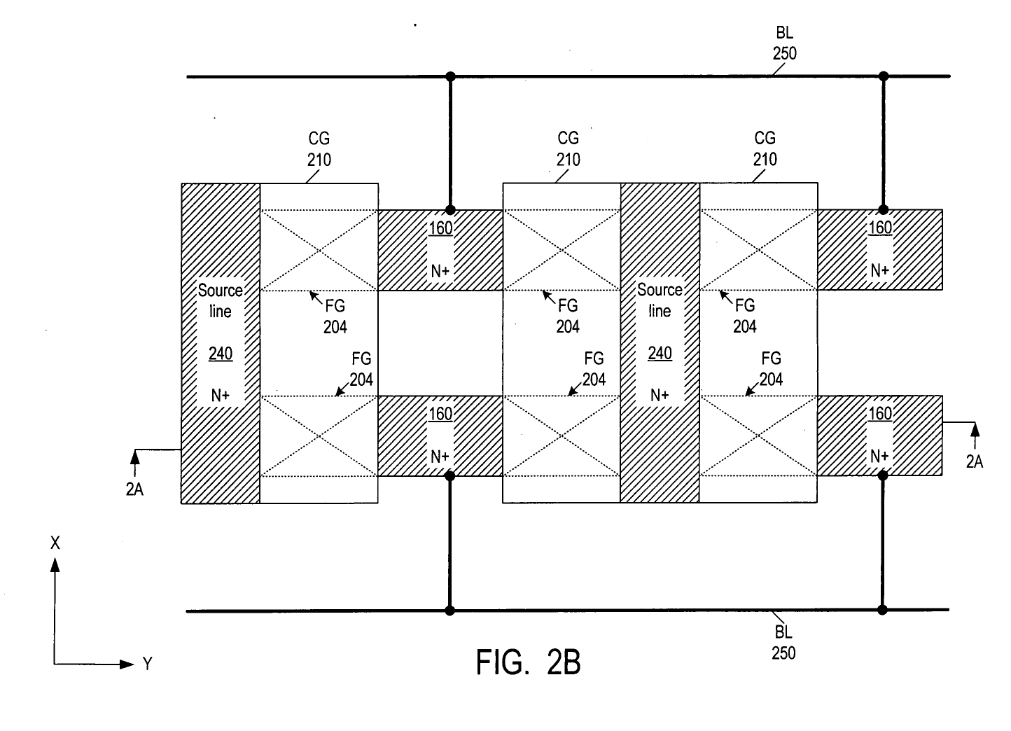

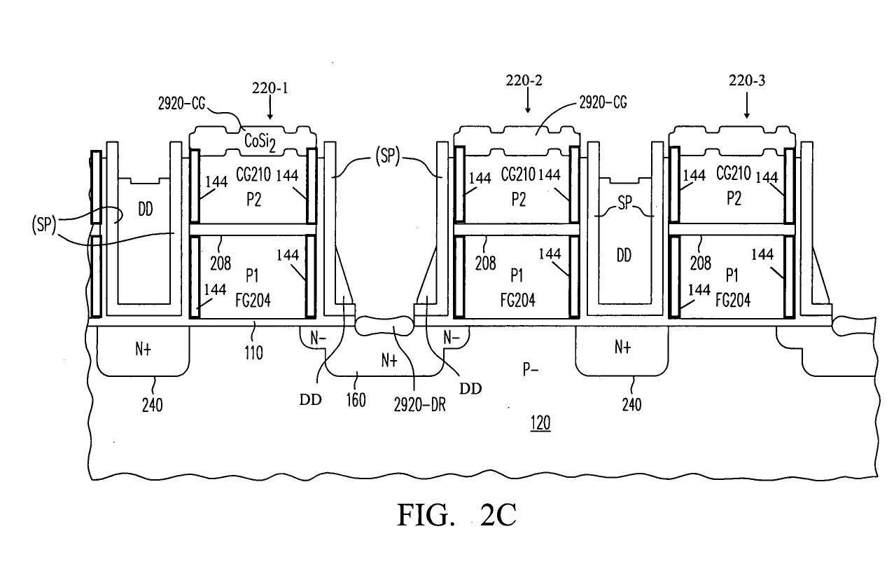

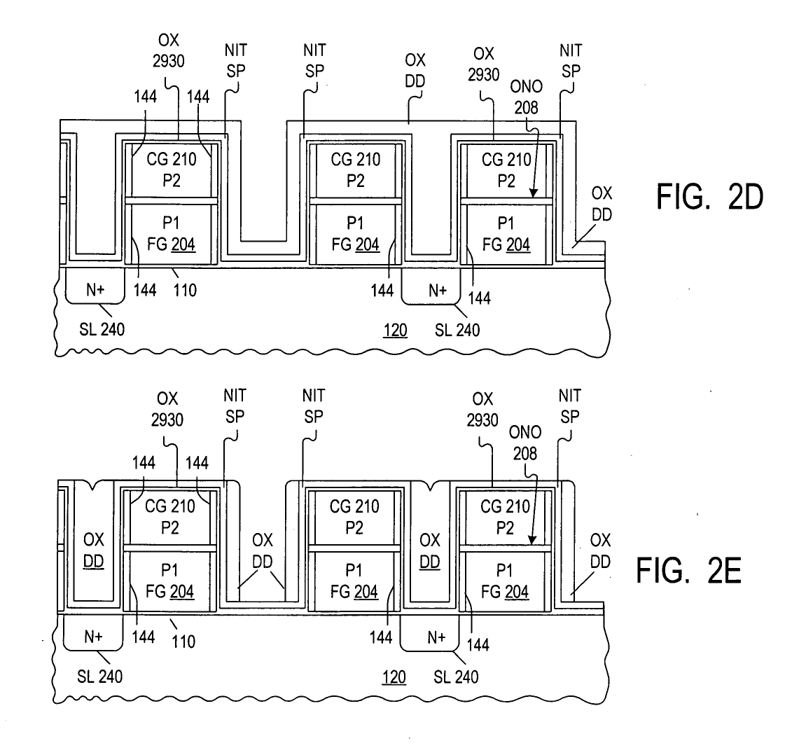

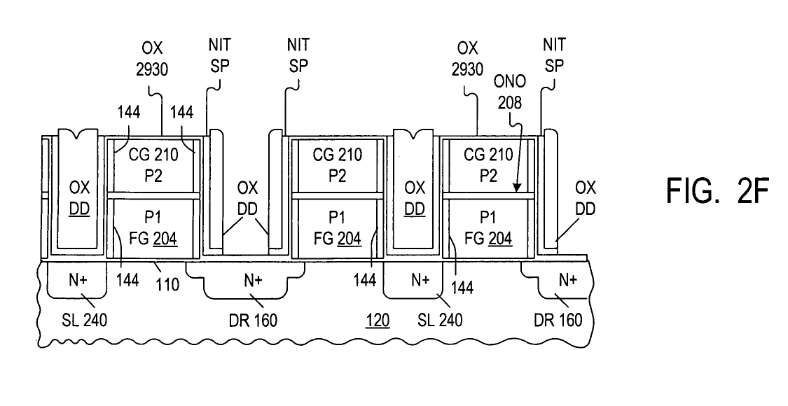

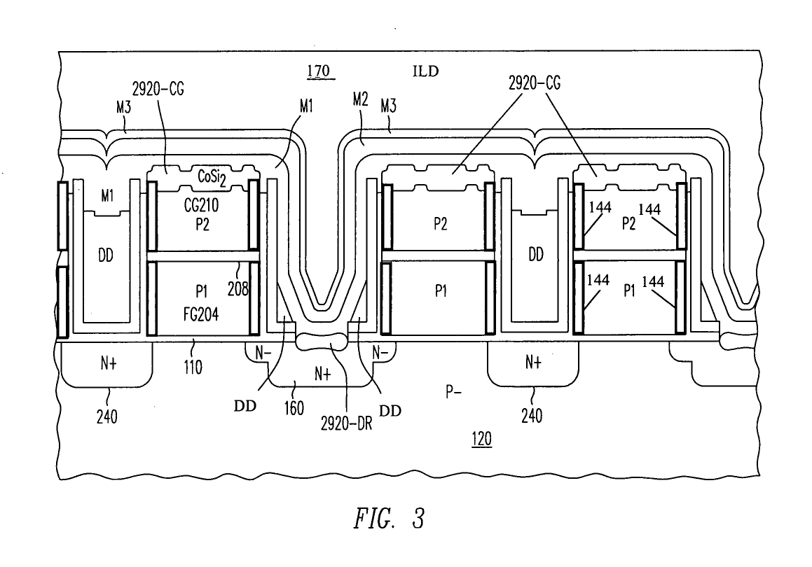

FIGS. 2A, 2B illustrate an integrated circuit at an intermediate stage of fabrication according to one embodiment of the present invention. FIG. 2A shows a vertical cross section marked “2A” in the top view of FIG. 2B. FIG. 2B shows silicon features but does not show dielectric layers. The integrated circuit is an ETOX type flash memory, fabricated in and over a P doped region of a monocrystalline silicon substrate 120. (The invention is not limited to flash memories, silicon circuits, particular dimensions, and other features, except as defined by the appended claims.) ETOX memories are described, for example, in U.S. Pat. No. 5,751,631 issued May 12, 1998 to Liu et. al.; European patent application EP1426974, both incorporated herein by reference.

Silicon dioxide layer 110 (FIG. 2A) is formed on substrate 120.

Oxide 110 includes gate oxide underneath floating gates (FG) 204 made from a doped polysilicon layer P1. The floating gates are marked with crosses in FIG. 2B. Dielectric 208 (e.g. ONO, i.e. a sandwich of silicon oxide, silicon nitride, silicon oxide) overlies the floating gates and separates them from control gates 210. Each memory cell includes a gate structure 220 (e.g. 220-1, 220-2, 220-3) which includes a floating gate 204 and a control gate 210.

As seen in FIG. 2B, each control gate 210 is part of a control gate line, marked with the same numeral 210, extending through the array in a row direction (X-direction). In this example, the control gate lines include a polysilicon layer P2 and a metal silicide (e.g. cobalt silicide) 2920-CG, shown in FIG. 2C, formed on polysilicon P2 to reduce the control gate resistance. FIG. 2C shows the same view as FIG. 2A after the metal silicide formation.

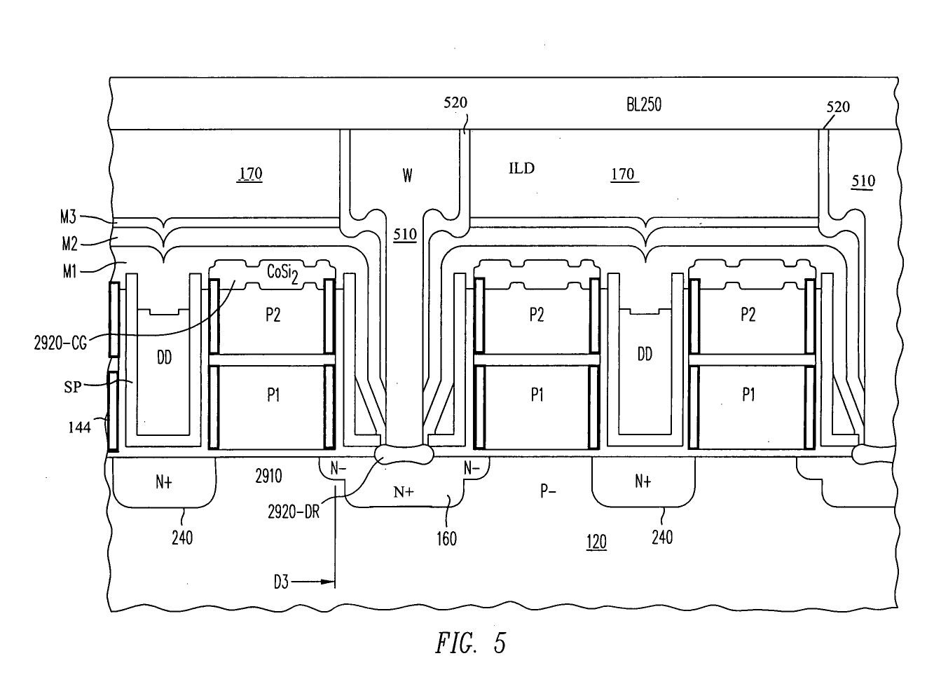

A source region 240 and a drain region 160 are N+ doped regions formed in substrate 120 on the opposite side of each gate structure 220. Drain regions 160 are silicided with a metal silicide (e.g. cobalt silicide) 2920-DR (FIG. 2C). All drain regions 160 in each column of memory cells are connected to a bitline 250 (shown in FIG. 5 and also schematically shown in FIG. 2B) extending in the column direction through the memory array. The bitlines have not been manufactured at the stage of FIGS. 2A-2C. Each drain region 160 is shared by two adjacent memory cells in the respective memory column. Each source region 240 is part of a source line 240 (FIG. 2B) running through the array in the row direction between adjacent control gate lines 210. Each source line is thus shared by two adjacent rows.

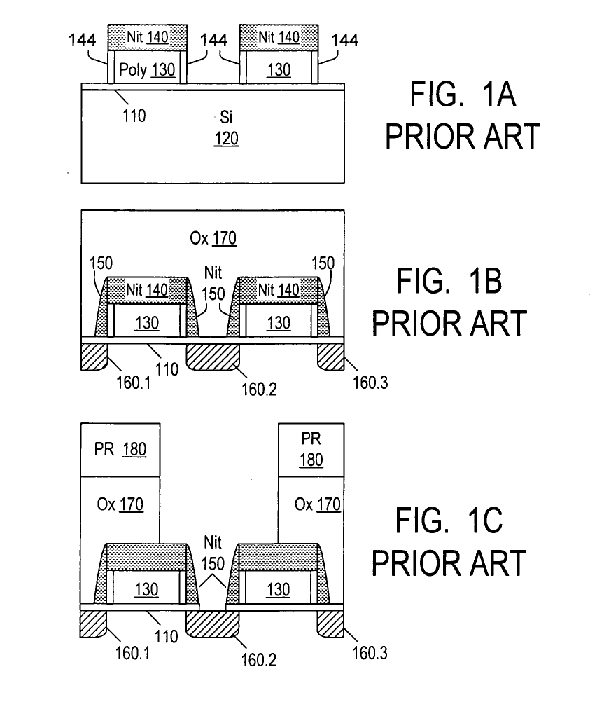

The sidewalls of floating gates 204 on the sides adjacent to source lines 240 and drain regions 160, and the sidewalls of polysilicon P2, are covered with silicon oxide 144. Each gate structure 220 includes a floating gate 204, the immediately underlying gate oxide 110, the immediately overlying portion of dielectric 208, the immediately overlying control gate 210 (a portion of control gate line), including the silicide 2920-CG, and the immediately adjacent sidewall oxide portions 144 will be referred to herein as a “gate structure”. Three gate structures 220 (220-1, 220-2, 220-3) are shown in FIG. 2A, and six gate structures are shown in FIG. 2B. In some embodiments, oxide 144 is omitted. Other variations are also possible for the gate structures. For example, a gate structure may have only one conductive gate (e.g. like in FIG. 1C).

In some illustrative embodiments of FIGS. 2A-2C, gate oxide 110 (underneath the floating gates 204) has a thickness of 85˜100 Å; layer P1 has thickness of 800˜1000 Å, ONO 208 is 160˜180 Å thick (the equivalent oxide thickness of 130˜150 Å), and layer P2 is 600˜1200 Å thick. Silicide 2920-CG is about 300 Å thick. The total height of each gate structure 220 is thus 1530˜2350 Å. The distance between the adjacent gate structures 220 sharing a drain region 160 (e.g. structures 220-1, 220-2) in the view of FIG. 2C is 0.22˜0.28 μm. The distance between the gate structures sharing a source region 240 e.g. structures 220-2, 220-3) is 0.1 μm.

Dielectric DD (FIGS. 2A, 2C) covers the substrate between control gates 210, except at the location of drain regions 160. The memory may also include field isolation (e.g. silicon dioxide, not shown) in areas not occupied by source lines 240 between adjacent memory columns.

In some embodiments, the memory is fabricated as illustrated in FIGS. 2D-2F. Silicon dioxide 110 is formed on substrate 120 by thermal oxidation. Doped polysilicon P1 is deposited and patterned as a number of long strips extending in the Y direction over the future positions of conductive floating gates 204 in each column. Substrate isolation regions can be formed before or after the polysilicon P1 deposition. For example, in some embodiments, the substrate isolation regions are formed using shallow trench isolation (STI). Substrate 120 is etched using the same mask as for polysilicon P1 (possibly a hard mask) to form trenches extending through the memory array in the column direction. The trenches are filled with dielectric. In other embodiments, substrate isolation is formed before the polysilicon deposition. These techniques are well known.

After the polysilicon P1 deposition and patterning, ONO 208 and conductive (doped) polysilicon P2 are deposited on the wafer. Polysilicon P2 is patterned photolithographically to form the polysilicon portions of control gate lines 210. Then ONO 208 and polysilicon P1 are etched away in the areas not covered by the control gate lines. Then thermal oxidation is performed to form silicon oxide 144 on the exposed sidewalls of layers P1 and P2. Oxide 144 can also be formed on the top of polysilicon P2, but this is not shown in the drawings. The thermal oxidation can be conducted at any suitable temperature, and in some embodiments the temperatures of 1000° C. or above are used to reduce the oxidation time. In some embodiments, oxide 144 is 30˜90 Å thick.

If the substrate isolation trenches extend through the array, the substrate isolation dielectric is etched out of the trenches at the locations of source lines 240. The etch is performed using a mask (not shown) which covers the areas between the control gate lines on the side of drain regions 160 but exposes the source lines 240. The mask does not have to be precisely aligned since the mask openings may overlap the gate structures.

Using the same mask, dopant is implanted into the wafer, e.g. by ion implantation, to dope the source lines 240 to N+.

Thin dielectric layer 2930 (FIGS. 2A, 2D), e.g. silicon dioxide, and then a thin silicon nitride layer SP, are deposited over the wafer. Dielectric DD is deposited over the wafer to fill the spaces between the control gate lines 210 over source lines 240 but not over drain regions 160 (the drain regions have not yet been doped at this stage). For example, dielectric DD can be silicon dioxide conformally deposited by CVD from TEOS to a thickness grater than one half of the distance between control gate lines 210 measured over source lines 240 but less than half the distance between control gate lines 210 measured over drains 160. Then dielectric DD is etched down anisotropically without a mask to a level at or slightly below the top surface of polysilicon P2 to form sidewall spacers over the future positions of drain regions 160 (see FIG. 2E). This etch stops on nitride SP over the drains 160 and control gate lines 210.

Nitride SP is etched away over the drain regions with oxide DD as a mask (FIG. 2F). Ion implantation is conducted to dope drain regions 160 to type N+. Then a thermal anneal is conducted, at an exemplary temperature of 1000˜1030° C. for 30 seconds, to activate the dopant in the drain regions and the source lines.

A short oxide etch (e.g. wet etch) removes silicon dioxide 2930 over polysilicon P2 and drain regions 160 (see FIG. 2A). If oxide 144 was formed on top of polysilicon P2 during the oxidation of polysilicon sidewalls, oxide 144 is removed from over polysilicon P2 by this etch.

Some of oxide DD is also removed. Then self-aligned silicidation is performed to form silicide 2920-CG, 2920-DR (FIG. 2C). Of note, in some embodiments, the silicide is cobalt silicide, which can be damaged by temperatures above 950° C.

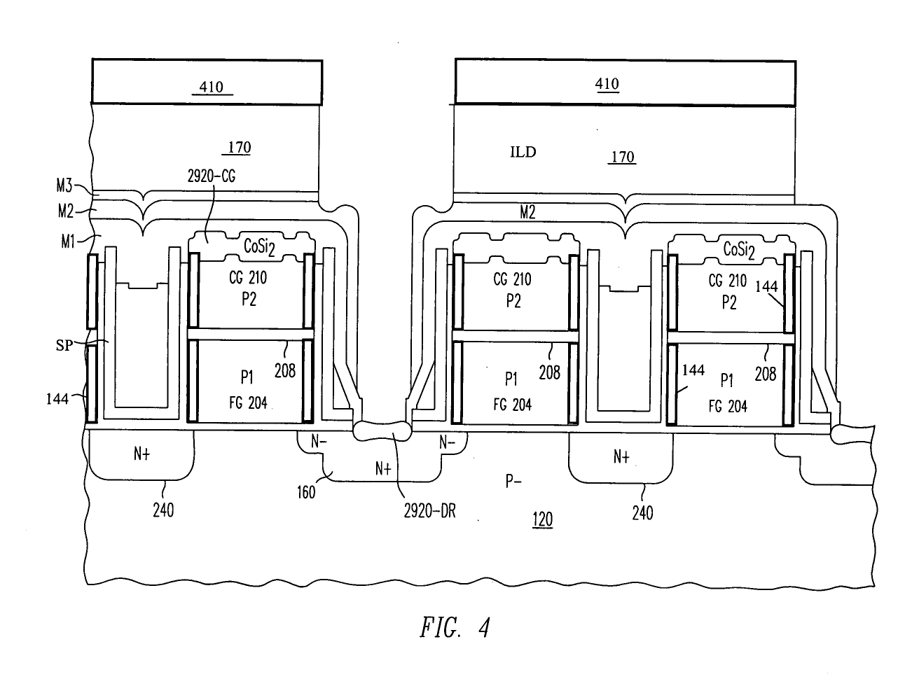

As shown in FIG. 3, a series of layers is then deposited on the structure of FIG. 2C. The first layer M1 of undoped silicon glass (USG) or silicon dioxide deposited from tetra-ethyl-ortho-silicate (TEOS) using plasma (PETEOS). Layer M1 may be conformal. Illustratively, layer M1 has a thickness of about 400˜500 Å. The M1 layer will protect the silicided layer 2920-CG atop the gate structures as well as the sidewall portions of layer SP at the sides of the gate structures from being eroded by subsequent etching steps. The M1 layer will not only serve as an etch stop when the M2 layer is being etched, but also serves as part of an isolation layer between silicon layer M3 (described below) and the gate structures, and between to-be-formed drain contacts 510 (FIG. 5) and the gate structures.

Next, the aspect ratio AR of the drain openings between the gate structures is increased by depositing the second dielectric layer M2, e.g. silicon nitride deposited by a plasma enhanced CVD, or silicon oxynitride (SION), or some other material. In some embodiments, this layer has a thickness of about 200˜400 Å at the top of gate structures 220. Because of non-conformal deposition, the M2 layer will be somewhat thinner at the bottom towards substrate 120 than at the top of gate structures 220. In some embodiments, this will be an advantage when the M2 layer is etched so that its lower portion closest to substrate 120 will be completely removed before its top portion is etched through. The M2 layer will serve as a part of etch stop layer during the etch of the ILD layer (PSG/BPSG).

Then a non-conformal layer M3 is deposited. In some embodiments, layer M3 is an undoped silicon layer deposited by PECVD. In some embodiments, layer M3 is 50˜70 Å thick at the top of gate structures 220, and 20˜40 Å thick over the drains 160. The layer M3 thickness gradually decreases from top to bottom over the gate structures' sidewalls.

Then a comparatively thick interlayer dielectric (ILD) 170 is deposited. Layer 170 may be PSG or BPSG deposited to an exemplary thickness of about 8500 Å using HDP (high density plasma) or in a furnace. Layer 170 fills the gaps between the gate structures 220. ILD 170 can be deposited to have a planar top surface, or its top surface can be planarized by chemical mechanical polishing (CMP) or other known techniques to facilitate the application of a photoresist mask (not shown).

The mask is formed on the wafer and patterned to expose the drain regions 160. Some embodiments use a hard mask 410 (FIG. 4) patterned using the photoresist mask. In some embodiments, mask 410 is made of polysilicon. As explained in U.S. Pat. No. 6,193,870, the hard mask may be desirable for better protection of the ILD layer. The mask openings may overlap control gate lines 210 and may also overlap the substrate regions between drains 160 in each row.

Then an etch is conducted to expose the silicide 2920-DR over drain regions 160. In some embodiments, the mask 410 remains in place throughout the etch, to be removed during the CMP of tungsten plugs 510 described below.

A first etching process using HBr/O2 cuts through hard mask 410 to ILD 170. In some embodiments, this process is reactive ion etching (RIE). In some embodiments, the etch is anisotropic, resulting in vertical or sloped sidewalls.

A second etching process is performed using C4F6/O2/Ar to etch through the ILD. The second etching process stops on layer M3. In some embodiments, this process is anisotropic reactive ion etching (RIE). In some embodiments, the sidewalls of ILD are vertical or slightly sloped (e.g. 86-88° above control gates 210).

A third etching process, using C4F6/CHF3/O2 as an etchant, now cuts through layers M3 and M2 at the bottom of the openings. In some embodiments, this process is anisotropic RIE. In some embodiments, layer M3 is also removed at the top of the gate structures, but part of M2 remains at the top due to a greater thickness of the M3 layer and possibly of the M2 layer. The third etching process stops on layer M1 at the bottom of the openings but may leave some of the M2 layer at the top of the gate structures.

A fourth etching process is now applied which cuts through layer M1 at the bottom of the opening to expose the silicide cap 2920-DR atop the drain regions 160. In some embodiments, this process is anisotropic RIE.

A layer 520 (FIG. 5) of silicon oxide is non-conformally deposited (e.g. by CVD from TEOS) to line the walls of the self-aligned contact opening. After the oxide is deposited, an anisotropic (preferentially vertical) oxide etch removes the bottom portion of oxide 520 from the bottom of the contact openings to expose silicide 2920-DR. Some of layer 520 remains on the openings' sidewalls to improve isolation between the contacts 510 (FIG. 5) and the gates.

Then the contact openings to drain regions 2920-DR are filled with conductive material 510 (FIG. 5). In some embodiments, layer 510 includes a thin barrier layer of Ti/TiN and also includes a tungsten plug. The tungsten is deposited after the barrier layer to fill the contact openings. Then the barrier layer and the tungsten are polished by CMP. The CMP also removes the hard mask 410.

A conductive layer 250 is deposited and patterned to form the bitlines.

Advantageously, in some embodiments, the self-aligned method for forming the contact openings to the drain regions makes the contact areas between the silicide regions 2920-DR and contacts 510 uniformly large. A non-self-aligned method could make these areas smaller due to a possible shift of the contacts 510 relative to the drain regions.

In some embodiments, layer M3 remains in the final structure. In some embodiments, even if silicon layer M3 contacts the contacts 510 (FIG. 5), the leakage between different contacts is insignificant due to layer M3 being very thin. The leakage can be further reduced by the oxide liner 520. In some embodiments, layer M3 is electrically floating, not being connected to any external terminal of the integrated circuit.

The invention is not limited to contacts to drain regions. Self-aligned contacts to source regions can be made using similar techniques. Also, the invention is not limited to non-volatile memories. In some embodiments, the contacts are made to source or drain regions of transistors such as shown in FIGS. 1A-1C. The invention is applicable to memories (e.g. DRAMS) and non-memory structures. What has been described is believed to be illustrative of the principles of the present invention. Further modifications will be apparent to those skilled in the art and may be made without, however, departing from the spirit and scope of the invention.

What is claimed is:

1. An integrated circuit comprising:
one or more gate structures, each said gate structure comprising at least one conductive gate;
one or more first source/drain regions, each said first source/drain region being adjacent to a sidewall of at least one of said one or more gate structures;
a first dielectric overlaying each said gate structure;
a first layer comprising silicon and overlaying a top of each said gate structure, the first layer being separated from each said conductive gate by the first dielectric;
a second dielectric overlaying each said gate structure and having one or more openings therethrough, each said opening overlying a respective one of said first source/drain regions;
one or more conductive contacts, each conductive contact having at least a portion located in a respective one of said one or more openings, the contact electrically contacting the respective first source/drain region in the opening, the contact being insulated from each the conductive gate of each gate structure adjacent to the contact.

2. An integrated circuit according to claim 1 wherein said first layer is thickest at the top of each said gate structure.

3. An integrated circuit according to claim 1 wherein each said gate structure includes metal silicide.

4. An integrated circuit according to claim 1 wherein the first layer is a silicon layer.

5. An integrated circuit according to claim 1, further comprising a dielectric separating each said conductive contact from the first layer.

6. An integrated circuit according to claim 1 wherein the first layer is electrically floating, not being connected to any external terminal of the integrated circuit.

7. An integrated circuit according to claim 1 further comprising one or more second source/drain regions, each said gate structure being located between one of said one or more first source/drain regions and one of said one or more second source/drain regions, wherein the first layer overlies the one or more second source/drain regions.

8. A method for fabricating an integrated circuit, the method comprising:
(1) forming one or more gate structures, each said gate structure comprising at least one conductive gate, and forming one or more source/drain regions, each said source/drain region being adjacent to a sidewall of at least one of said one or more gate structures;
(2) forming a first layer overlaying a top of-each said gate structure and overlaying each said sidewall and each said source/drain region, the first layer being thicker over each said gate structure than over each said source/drain region;
(3) forming a dielectric overlaying each said gate structure and each said source/drain region;
(4) etching the dielectric selectively to the first layer to form one or more openings in the dielectric over said one or more source/drain regions, each said opening exposing the first layer;
(5) etching at least the first layer in each said opening to provide electrical contact to each said source/drain region in the opening.

9. The method of claim 8 wherein at least one of said one or more openings in the dielectric exposes the first layer over at least one of said one or more gate structures.

10. The method of claim 8 wherein the first layer comprises silicon.

11. The method of claim 8 wherein operation (1) comprises ion implantation of said one or more source/drain regions followed by heating said one or more source/drain regions to anneal said one or more source/drain regions; and
the method further comprises, after operation (1) but before operation (2):
depositing a metal containing layer;
heating the metal containing layer to react the metal with silicon in each said conductive gate and/or in each said source/drain region, and then removing unreacted metal.

12. The method of claim 8 wherein operation (1) comprises heating each said conductive gate to oxidize sidewalls of each said conductive gate; and
the method further comprises, after operation (1) but before operation (2):
depositing a metal containing layer;
heating the metal containing layer to react the metal with silicon in each said conductive gate and/or in each said source/drain region, and then removing unreacted metal.

13. A method for fabricating an integrated circuit, the method comprising:
(1) forming one or more gate structures, each said gate structure comprising at least one conductive gate, and forming one or more source/drain regions each of which is adjacent to a sidewall of at least one of said one or more gate structures;
(2) forming a first dielectric over each said gate structure;
(3) forming a first layer comprising silicon and overlaying a top of each said gate structure and overlaying each said sidewall and each said source/drain region, the first layer being separated from each said conductive gate by the first dielectric;
(4) forming a second dielectric overlaying each said gate structure and each said source/drain region;
(5) etching the second dielectric selectively to silicon to form one or more openings in the second dielectric over said one or more source/drain regions, each said opening exposing the first layer;
(6) etching at least the first layer in each said opening to provide electrical contact to each said source/drain region in the opening.

14. The method of claim 13 wherein operation (1) comprises ion implantation of said one or more source/drain regions followed by heating said one or more source/drain regions to anneal said one or more source/drain regions; and
the method further comprises, after operation (1) but before operation (2):
depositing a metal containing layer;
heating the metal containing layer to react the metal with silicon in each said conductive gate and/or in each said source/drain-region, and then removing unreacted metal.

15. The method of claim 13 wherein operation (1) comprises heating each said conductive gate to oxidize sidewalls of each said conductive gate; and
the method further comprises, after operation (1) but before operation (2):
depositing a metal containing layer;
heating the metal containing layer to react the metal with silicon in each said conductive gate and/or in each said source/drain region, and then removing unreacted metal.

16. A method for fabricating an integrated circuit, the method comprising:
(1) forming one or more gate structures, each said gate structure comprising at least one conductive gate;
(2) implanting dopant to form one or more source/drain regions, each said source/drain region being adjacent to a sidewall of at least one of said one or more gate structures;
(3) heating said one or more source/drain regions to anneal said one or more source/drain regions;
(4) after operation (3): (a) depositing a metal containing layer, (b) heating the metal containing layer to react the metal with silicon in each said conductive gate and/or in each said source/drain region, and then (c) removing unreacted metal;
(5) after operation (4), forming a first layer overlaying a top of each said gate structure and overlaying each said sidewall and each said source/drain region;
(6) forming a dielectric overlaying each said gate structure and each said source/drain region;
(7) etching the dielectric selectively to the first layer to form one or more openings in the dielectric over said one or more source/drain regions, each said opening exposing the first layer;
(8) etching at least the first layer in each said opening to provide electrical contact to each said source/drain region in the opening.
